(19) United States
(12) Patent Application Publication
(10) Pub. No.: US 2008/0059853 A1
(43) Pub. Date: Mar. 6, 2008

(54) Semiconductor Integrated Circuit

(75) Inventor: Masanori Ushikubo, Yamanashi (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: Oki Electric Industry Co., Ltd., Tokyo (JP)

(21) Appl. No.: 11/749,968

(22) Filed: May 17, 2007

(30) Foreign Application Priority Data
Aug. 30, 2006 (JP) 2006-234295

(51) Int. Cl. G01R 31/28

(52) U.S. Cl. 714/726

(57) ABSTRACT

A semiconductor integrated circuit. A scan mode is set and test data is set in a scan chain of S-FFs 4 and 2B. The circuit switches to normal mode and a first pulse of a clock signal CLK is provided. Outputs of combinational circuit 1A, acquired by S-FFs 2B, and a signal, in which data retained at S-FF 4 is inverted, are provided to combinational circuit 1B. A second pulse is provided, and the output of combinational circuit 1B is retained at other S-FFs 2C. The circuit switches to the scan mode, and the signals retained at S-FFs 2C are read out and judged. An interval between the first and second clock pulses of the clock signal CLK is varied to perform a delay test. Thus, even if a hardware macro such as a RAM 3 is included, a delay test by scanning is possible.

### CROSS-REFERENCE TO RELATED APPLICATION

This application claims priority under 35 USC 119 from Japanese Patent Application No. 2006-234295, the disclosure of which is incorporated by reference herein.

### BACKGROUND OF THE INVENTION

1. Field of the Invention

The present invention relates to a semiconductor integrated circuit equipped with a scan test function, and more particularly to a semiconductor integrated circuit at which delay testing by scanning is possible.

2. Description of the Related Art

FIG. 2 is a schematic structural diagram of a previous semiconductor integrated circuit equipped with a scan test function, which is described in the reference “RTL Design Style Guide, Verilog HDL Version” (corporate), from the Semiconductor Technology Academic Research Center (STARC) (pp. 3-48 to 3-50).

This semiconductor integrated circuit includes a combinational circuit 1B which is a test object, and a combinational circuit 1A preceding the combinational circuit 1B. Scan flip-flops 2B1, 2B2, . . . , 2Bm are connected between these combinational circuits 1A and 1B. (Below, flip-flops are referred to with “FF” and scan flip-flops are referred to with “S-FF”.) This semiconductor integrated circuit further includes a hardware macro such as a RAM (random access memory) 3 or the like. An output side of the RAM 3 is connected to an input side of the combinational circuit 1B via an S-FF 4 and a selector 5.

An S-FF is structured with a selector and an FF. The selector selects either a signal from a preceding combinational circuit or the like or a scan enable signal SE. The FF retains the signal selected by the selector at the time of a clock signal, and outputs the retained signal.

Signals which are outputted in parallel from the combinational circuit 1A are provided to first inputs of the selectors in the S-FFs 2B1, . . . , 2Bm, respectively. The signals, which are outputted from the FFs in these S-FFs 2B1, . . . , 2Bm, are provided in parallel to the input side of the combinational circuit 1B. The output sides of the FFs in the S-FFs 2B1, 2B2, . . . , 2Bm-1 are also connected to second inputs of the selectors in the S-FFs 2B2, 2B3, . . . , 2Bm, respectively.

An output side of the RAM 3 is connected to a first input of the selector in the S-FF 4 and a first input of the selector (SEL) 5. The output side of the FF in the S-FF 4 is connected to a second input of the selector 5 and to a second input of the selector in the S-FF 2B1. A second input of the selector in the S-FF 4 is connected to a scan input terminal 6B. An output side of the FF in the S-FF 2Bm is connected to a scan output terminal 7B. Thus, a scan chain is structured.

Meanwhile, at the input side of the combinational circuit 1A, signals are provided in parallel from S-FFs 2A1, 2A2, . . . , 2Ak, which similarly structure a scan chain. The second input of the selector of the S-FF 2A1 is connected to a scan input terminal 6A. The output side of the FF in the S-FF 2Ak is connected to a scan output terminal 7A.

Further, the output side of the combinational circuit 1B is connected with S-FFs 2C1, 2C2, . . . , 2Cn, which similarly structure a scan chain. The second input of the selector in the S-FF 2C1 is connected to a scan input terminal 6C, and the output side of the FF in the S-FF 2Cn is connected to a scan output terminal 7C. A clock signal CLK, which is provided from a clock terminal 8, is supplied to a clock terminal of the FF in each S-FF, via clock supply paths. The scan enable signal SE, which is provided from a terminal 9, is provided to a control terminal of the selector in each S-FF. Furthermore, a test signal TST, for instructing normal operations or test operations, is provided to a control terminal of the selector 5 from a terminal 10.

In this semiconductor integrated circuit, at a time of fabrication, a scan test of the combinational circuits 1A and 1B is conducted using the S-FFs.

In the scan test, firstly, a scan mode is specified by the scan enable signal SE, and the selector in each S-FF switches to the second input. Thus, a scan chain from the scan input terminal 6A to the S-FF 2A1, the S-FF 2A2, . . . , the S-FF 2Ak, and to the scan output terminal 7A is formed. Similarly, a scan chain from the scan input terminal 6B to the scan output terminal 7B and a scan chain from the scan input terminal 6C to the scan output terminal 7C are formed.

Next, synchronously with the clock signal CLK, serial input signals for testing SIA and SIB are inputted from the scan input terminals 6A and 6B. Hence, testing data are shifted and retained at the FFs in the S-FFs which structure the scan chains. These testing data are provided in parallel to the input sides of the combinational circuits 1A and 1B.

Then, a normal mode is specified by the scan enable signal SE, the selectors in the S-FFs switch to the first inputs, and a single (first) pulse of the clock signal CLK is provided. Hence, output signals of the combinational circuit 1A are retained at the FFs in the S-FFs 2B1, . . . , 2Bm. Meanwhile, output signals of the combinational circuit 1B are retained at the FFs in the S-FFs 2C1, . . . , 2Cn.

Thereafter, the scan mode is specified by the scan enable signal SE, the selectors in the S-FFs again switch to the second inputs, and the clock signal CLK is provided. Hence, the output signals of the combinational circuit 1A, which are retained at the FFs in the S-FFs 2B1, . . . , 2Bm, are outputted from the scan output terminal 7B synchronously with the clock signal, to be serial output signals SOB. Meanwhile, the output signals of the combinational circuit 1B, which are retained at the FFs in the S-FFs 2C1, . . . , 2Cn, are outputted from the scan output terminal 7C synchronously with the clock signal to be serial output signals SOC.

Hence, signals that should be outputted from the combinational circuits in response to the serial input signals SIA and SIB are compared with the serial output signals SOB and SOC that are actually outputted. In this manner, it is possible to test whether or not the combinational circuits 1A and 1B are operating normally. Note that hardware macros, such as the RAM 3, are not subjects of the scan test. Testing of such hardware macros is implemented with separately installed BIST (built-in self-test) circuits.

A semiconductor integrated circuit for which normal operations have been verified by scan testing and BIST is incorporated and used in a product. When the semiconductor integrated circuit is being incorporated into the product, the terminals 9 and 10 are fixedly connected such that the selectors in the S-FFs and the selector 5 are switched to the first inputs (see, for example, Japanese Patent Application Laid-Open (JP-A) No. 2005-257290 and Japanese Patent Application No. 2005-116468).

However, there remains a problem with the above-described semiconductor integrated circuit, in that a delay test cannot be performed by scanning. An exemplary procedure of a delay test is as follows. Firstly, set test data with the S-FFs 2B1, . . . , 2Bm at the input side of the combinational circuit 1B. Secondly, acquire signals outputted from the combinational circuit 1B with the output side S-FFs 2C1, . . . , 2Cm at a certain duration after the time of the setting. Finally, judge whether predetermined output signals have been outputted from the combinational circuit 1B during the certain duration. In this manner, the delay test tests an operational delay duration of the combinational circuit. One reason why the delay test cannot be performed in the semiconductor integrated circuit of FIG. 2 is as follows.

At the S-FFs 2B1, . . . , 2Bm, transitions from “1” to “0” and from “0” to “1” are caused by data being provided from the preceding S-FFs 2A1, . . . , 2Ak and signals being outputted from the combinational circuit 1A, and the following combinational circuit 1B can be tested. However, at the S-FF 4, the RAM 3 is directly connected to a system operation path. Consequently, it is not possible to specify a logical state, of “0” or “1”, at the output of the RAM 3 with a scan function. Therefore, signal switching cannot be caused, and testing of the combinational circuit 1B following the S-FF 4 is not possible.

### SUMMARY OF THE INVENTION

The present invention is to provide a semiconductor integrated circuit at which a delay test by scanning can be realized, even if a hardware macro such as a RAM or the like is included.

An aspect of the present invention is a semiconductor integrated circuit comprising: a first scan flip-flop that outputs a signal, which is disposed at an input side of the semiconductor integrated circuit; a hardware macro that outputs another signal; a combinational circuit that performs a logical operation based on the signal provided from the first scan flip-flop and the signal provided from the hardware macro, and outputs a logical operation result signal; a second scan flip-flop that is disposed at an output side of the combinational circuit; a third scan flip-flop that, structures a scan chain with the first scan flip-flop when a scan mode is specified and inverts retained data in accordance with a clock signal when a normal mode is specified; and a selector that selects the signal outputted from the hardware macro during a normal operation, selects the retained data of the third scan flip-flop during a test operation, and provides the selected signal or data to the combinational circuit.

In the semiconductor integrated circuit of the present invention when the scan mode is specified, a scan chain is constituted with the first S-FF. At the third S-FF that is provided, retained data is inverted in accordance with the clock signal when the normal mode is specified. The selector that is provided selects the signal outputted from the hardware macro at a time of normal operations and selects the retained data of the third S-FF at the time of the test operation, and supplies the selected signal to the combinational circuit, which is a test subject. Therefore, a delay test by scanning can be realized with the following procedure.

Firstly, the circuit is set to the scan mode, a scan chain is formed with the first S-FF and the third S-FF, and test data is set. Then, the circuit switches to the normal mode and a single (first) pulse of the clock signal is provided. Accordingly, a signal of an inversion of the data retained at the third S-FF together with either an output signal of a preceding combinational circuit which has been acquired by the first S-FF, or an input signal provided from an external terminal, are provided to the test subject combinational circuit. Thereafter, when a second pulse of the clock signal is provided, an output signal from the test subject combinational circuit is retained at the second S-FF.

Then, the circuit switches back to the scan mode, the output signal of the combinational circuit which has been retained at the second S-FF is read out, and it is judged whether or not a desired logical operation result has been outputted. By performing delay tests with an interval between the first and second pulses of the clock signal being altered, an operational delay duration of the test subject combinational circuit can be tested. Therefore, it is possible to realize a delay test by scanning even with a semiconductor integrated circuit that includes a hardware macro such as a RAM or the like.

### BRIEF DESCRIPTION OF THE DRAWINGS

A preferred exemplary embodiment of the present invention will be described in detail based on the following figures, wherein:

FIG. 1 is a schematic structural diagram of a semiconductor integrated circuit which illustrates an exemplary embodiment of the present invention;

FIG. 2 is a schematic structural diagram of a conventional semiconductor integrated circuit, provided with a conventional scan test function; and

FIG. 3 is a signal waveform chart illustrating the operation of the semiconductor integrated circuit of FIG. 1 during a delay test.

### DETAILED DESCRIPTION OF THE INVENTION

The foregoing and other objects and novel features of the present invention will be apparent from the following description of preferred embodiments of the invention, taken in conjunction with the accompanying drawings. The drawings are merely for purposes of description and do not limit the scope of the present invention.

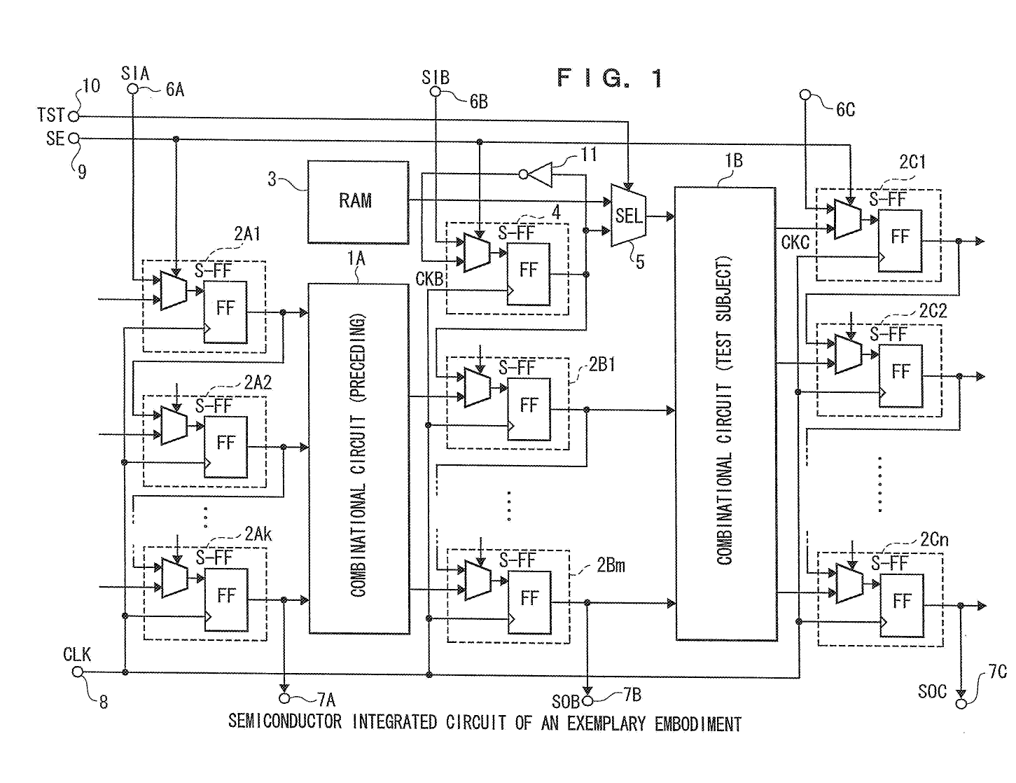

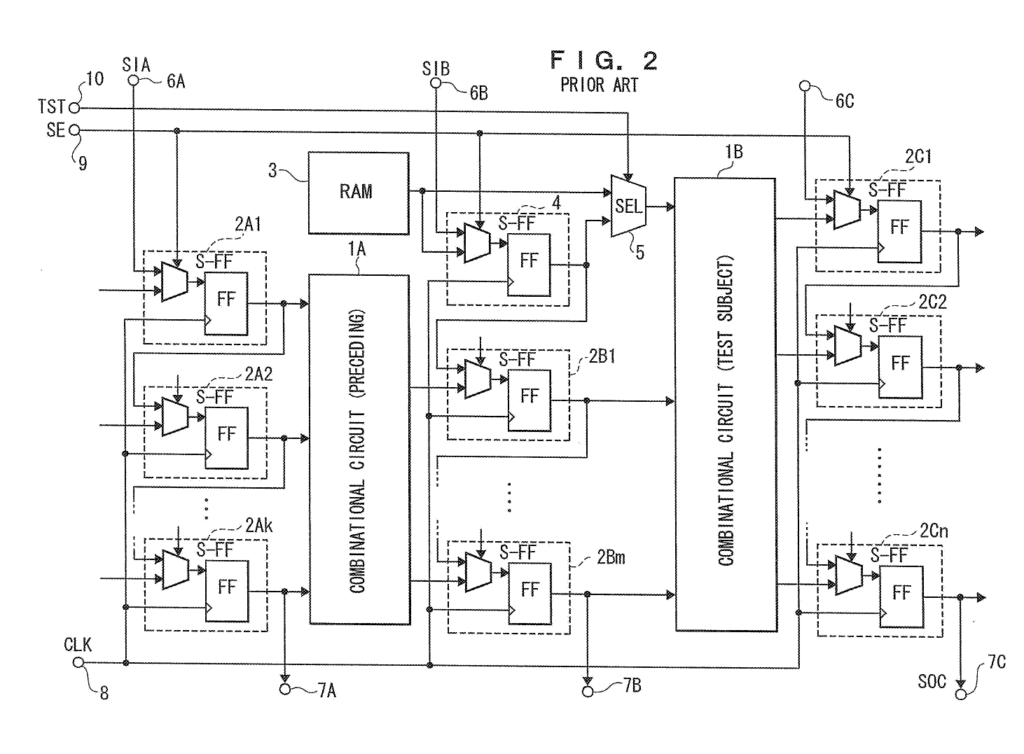

FIG. 1 is a structural diagram of a semiconductor integrated circuit which illustrates an exemplary embodiment of the present invention. Elements in common with elements in FIG. 2 are assigned the same reference numerals.

The semiconductor integrated circuit of FIG. 1 includes the test subject combinational circuit 1B and the preceding combinational circuit 1A, connected by the S-FFs 2B1, 2B2, . . . , 2Bm. The semiconductor integrated circuit also includes the S-FF 4, the selector 5, and a hardware macro such as the RAM 3 or the like.

The output side of the RAM 3 is connected to the first input of the selector 5. The output side of the selector 5 is connected to the input side of the combinational circuit 1B. The second input of the selector in the S-FF 4 is connected to the scan input terminal 6B. The output side of the FF in the S-FF 4 is connected, via an inverter 11, to the first input of the selector in the S-FF 4.

The output side of the FF in the S-FF 4 is also connected to the second input of the selector 5 and the second input of the selector in the S-FF 2B1. Further, the output side of the FF in the S-FF 2Bm is connected to the scan output terminal 7B.

Signals which are outputted in parallel from the combinational circuit 1A are provided to the first inputs of the selectors in the S-FFs 2B1, . . . , 2Bm, respectively. The signals which are outputted from the FFs in the S-FFs 2B1 to 2Bm are provided in parallel to the input side of the combinational circuit 1B. The output sides of the FFs in the S-FFs 2B1, 2B2, . . . , 2Bm-1 are also connected to the second inputs of the selectors in the S-FFs 2B2, 2B3, . . . , 2Bm, respectively.

At the input side of the combinational circuit 1A, signals are provided in parallel from the S-FFs 2A1, 2A2, . . . , 2Bk, which similarly constitute a scan chain. The second input of the selector in the S-FF 2A1 is connected to the scan input terminal 6A. The output side of the FF of the S-FF 2Ak is connected to the scan output terminal 7A.

At the output side of the combinational circuit 1B, the S-FFs 2C1, 2C2, . . . , 2Cn, which similarly constitute a scan chain, are connected. The second input of the selector in the S-FF 2C1 is connected to the scan input terminal 6C, and the output side of the FF in the S-FF 2Cn is connected to the scan output terminal 7C.

The clock signal CLK which is provided from the clock terminal 8 is supplied to the clock terminals of the FFs in the S-FFs via the clock supply paths. The scan enable signal SE provided from the terminal 9 is provided to the control terminals of the FFs in the S-FFs. The test signal TST, for instructing normal operations or test operations, is provided to the control terminal of the selector 5 from the terminal 10.

Next, operation of the above-described semiconductor integrated circuit will be described.

For this semiconductor integrated circuit, scan tests and delay tests of the combinational circuits 1A and 1B are carried out at a time of fabrication, using the S-FFs. For a scan test, test operations are instructed by the test signal TST provided to the terminal 10, and the selector 5 switches to the second input. Hence, the RAM 3 is disconnected and a test of logical operations of the combinational circuits 1A and 1B is carried out. This operation is similar to the scan test operation for the semiconductor integrated circuit of FIG. 2, and will not be described here.

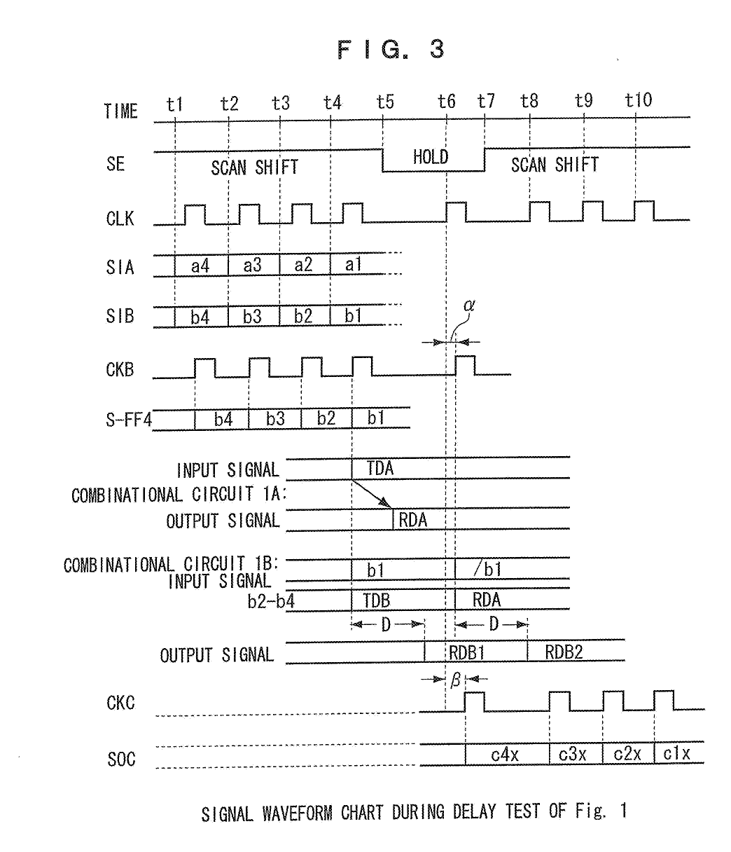

FIG. 3 is a signal waveform chart illustrating operation of the semiconductor integrated circuit of FIG. 1 during a delay test. Herebelow, operation of the delay test of the circuit of FIG. 1 will be described with reference to FIG. 3.

Here, numbers of input terminals and output terminals of the combinational circuits 1A and 1B are each four. Herein, a case of testing a delay duration, from the provision of test data to the input side of the test subject combinational circuit 1B until the output of logical calculation result signals at the output side, will be described. The clock signal CLK is provided through the clock terminal 8 and propagated to the S-FF 4 and each S-FF 2B to serve as a clock signal CKB, being delayed by a duration α, and is propagated to each S-FF 2C to serve as a clock signal CKC, being delayed by a duration β. The test signal TST from the terminal 10 is set to “H” to instruct test operations, and the selector 5 is switched to the second input (i.e., the S-FF 4 output side).

Firstly, “H”, instructing the scan mode, is specified by the scan enable signal SE and the selectors of all the S-FFs switch to the second input sides. Thus, each of the FFs of the S-FFs 2A1, . . . , 2A4 are connected in a cascade arrangement, and a shift register (scan chain) reaching from the scan input terminal 6A to the scan output terminal 7A is constituted. The signals which are outputted from the FFs of the S-FFs 2A1, . . . , 2A4 are provided in parallel to the combinational circuit 1A. Similarly, each of the FFs of the S-FF 4 and the S-FFs 2B1, . . . , 2B3 are connected in a cascade arrangement, and a shift register reaching from the scan input terminal 6B to the scan output terminal 7B is constituted. The signals which are outputted from the FFs of the S-FF 4 and the S-FFs 2B1, . . . , 2B3 are provided in parallel to the combinational circuit 1B.

At a time t1 in FIG. 3, the scan input signals SIA and SIB provided to the scan input terminals 6A and 6B are set to “a4” and “b4”, respectively, in accordance with predetermined test data TDA and TDB, In addition, a pulse of the clock signal CLK is provided through the clock terminal 8. Accordingly, after a propagation delay along each clock supply path, the data “a4” and “b4” are acquired by the S-FFs 2A1 and 2B1, respectively.

Thereafter, at times t2, t3, and t4, scan input signals SIA (“a3”, “a2” and “a1”) are sequentially provided through the scan input terminal 6A to the S-FFs 2A1, . . . , 2A4, being sequentially shifted in accordance with the clock signal CLK. Meanwhile, scan input signals SIB (“b3”, “b2” and “b1”) are sequentially provided through the scan input terminal 6B and sequentially shifted to the S-FF 4 and the S-FFs 2B1, . . . , 2B3. As a result of the above-described scan shift operation, the test data TDA (“a1”, “a2”, “a3” and “a4”) are retained at the FFs in the S-FFs 2A1, . . . , 2A4, and are provided in parallel to the combinational circuit 1A. Meanwhile, the test data TDB (“b1”, “b2”, “b3” and “b4”) are retained at the FFs in the S-FF 4 and the S-FFs 2B1, . . . , 2B3 and provided in parallel to the combinational circuit 1B. The combinational circuit 1A carries out logical processing in accordance with the test data TDA and, after a predetermined processing period, outputs processing result signals RDA in parallel. Meanwhile, the combinational circuit 1B carries out logical processing in accordance with the test data TDB and, after a predetermined processing period D, outputs processing result signals RDB1 in parallel.

At a time t5, the scanning enable signal SE from the terminal 9 is set to “L”, which instructs the normal mode, and the selectors in all the S-FFs switch to the first input sides. As a result, the signals RDA which are outputted from the combinational circuit 1A are provided to the input sides of the FFs of the S-FFs 2B1, . . . , 2B3. Meanwhile, the test datum that has been retained at the FF in the S-FF 4 (“b1” ) is inverted by the inverter 11 and provided to the input side of the same FF in the S-FF 4. Now, at the time t5, the clock signal CLK is not provided to the clock terminal 8, so contents of the FFs in the S-FFs 4 and 2B1, . . . , 2B3 do not change.

At a time t6, a clock signal CLK for holding (retaining) is provided from the clock terminal 8. The clock signal CLK is delayed by the duration α and provided to the S-FFs 4 and 2B1, . . . , 2B3 as the clock signal CKB. As a result, the inverted test data (“/b1”) is acquired by the FF in the S-FF 4, and the signals RDA which are outputted from the combinational circuit 1A at this point in time are acquired by the FFs in the S-FFs 2B1, . . . , 2B3.

Meanwhile, the clock signal CLK is delayed by the duration β and provided to the S-FFs 2C1, . . . , 2C4 as the clock signal CKC. Thus, the signals RDB1 which are outputted from the combinational circuit 1B at this point in time (“c1x”, “c2x”, “c3x” and “c4x”) are acquired by the FFs in the S-FFs 2C1, . . . , 2C4. Accordingly, a scan output signal SOC, which is outputted to a shift output terminal 7C from the output side of the S-FF 2C4, is at “c4x”. In the combinational circuit 1B, logical processing is commenced on the basis of the signals RDA which have been just been acquired by the FFs in the S-FFs 4 and 2B1, . . . , 2B3.

At a time t7, the scanning enable signal SE returns to “H”, the selectors of all the S-FFs switch to the second input sides, and the circuit is again in a scan shift operation state.

At times t8, t9 and t10, after the duration β from each rise of the clock signal CLK, the contents of the FFs in the S-FFs 2C1, . . . , 2C4 are sequentially shifted, and are serially outputted as scan output signals SOC from the scan output terminal 7C. Thus, the scan output signals SOC outputted from the scan output terminal 7C are the pre-change signals RDB1 from the combinational circuit 1B.

Hence, the scan output signals SOC which are actually outputted from the scan output terminal 7C are compared with expected values based on the input data RDA of the combinational circuit 1B and logical circuit conditions and thus detection of an unusual delay duration of the clock supply paths or the like is possible. For example, if the delay duration β of the clock signal CKC for the S-FFs 2C1, . . . , 2C4 is large, that is, if a condition such that α+D<β applies, post-change output signals RDB2 of the combinational circuit 1B will be acquired by the FFs in the S-FFs 2C1, . . . , 2C4 in accordance with the clock signal CLK for holding. In consequence, the scan output signals SOC which are actually outputted from the scan output terminal 7C will not match the expected values based on the input data RDA and the logical circuit conditions. Thus, it is possible to judge if there is some delay fault.

As described above, the semiconductor integrated circuit of the present exemplary embodiment inverts test data “b1” provided to the test subject combinational circuit 1B in accordance with a timing of the clock signal CKB. Accordingly, the circuit is structured such that the output signal of the S-FF 4 is fed back via the inverter 11 to the first input of the selector in the S-FF 4. Therefore, during a delay test, it is possible to alter the test data provided to the combinational circuit 1B (i.e., “b1”, “b2”, “b3”) and “b4”) all at one time in accordance with the clock signal CLK for holding. Thus, it is possible to realize a delay test by scanning even though the semiconductor integrated circuit includes a hardware macro such as the RAM 3.

Note that the present invention is not limited to the exemplary embodiment described above, and various modifications are possible. Variant examples thereof are, for example, as follows.

(a) The exemplary embodiment described above has been illustrated with the RAM 3 serving as an example of a hardware macro, but application is similarly possible in respect to other hardware macros with which scan tests are not possible.

(b) The semiconductor integrated circuit of FIG. 1 includes plural scan chains, but application is similarly possible to a circuit with a single scan chain.

(c) In the exemplary embodiment described above, at a time of normal operations, data are provided in parallel from the combinational circuit 1A to the S-FFs 2B1, . . . , 2Bm. However, if the preceding combinational circuit 1A were not present, data could be provided in parallel to the S-FFs 2B1, . . . , 2Bm through external terminals.

(d) In the exemplary embodiment described above, the output signal of the S-FF 4 is inverted by the inverter 11 and fed back to the first input of the selector in the S-FF 4. However, an inverted output terminal of the FF in the S-FF 4 could simply feed back as is to the selector in the S-FF 4.

What is claimed is:

1. A semiconductor integrated circuit comprising:
a first scan flip-flop that outputs a signal, which is disposed at an input side of the semiconductor integrated circuit;
a hardware macro that outputs another signal;
a combinational circuit that performs a logical operation based on the signal provided from the first scan flip-flop and on the signal provided from the hardware macro, and outputs a logical operation result signal;
a second scan flip-flop that is disposed at an output side of the combinational circuit;
a third scan flip-flop that configures a scan chain with the first scan flip-flop when a scan mode is set, and that inverts retained data in accordance with a clock signal when a normal mode is set; and
a selector that selects the signal outputted from the hardware macro during normal operation, and that selects the retained data of the third scan flip-flop during test operation and provides the selected signal or data to the combinational circuit.

2. The semiconductor integrated circuit of claim 1, wherein the hardware macro comprises a RAM.

3. The semiconductor integrated circuit of claim 1, wherein a plurality of the scan chains are configured.

4. The semiconductor integrated circuit of claim 1, further comprising a second combinational circuit that is disposed at an input side of the first scan flip-flop and provides a signal to the first scan flip-flop.

5. A semiconductor integrated circuit comprising:
a first scan flip-flop that outputs a signal, which is disposed at an input side of the semiconductor integrated circuit;
a hardware macro that outputs another signal;
a combinational circuit that performs a logical operation based on the signal provided from the first scan flip-flop and on the signal provided from the hardware macro, and outputs a logical operation result signal;
a second scan flip-flop that is disposed at an output side of the combinational circuit;
a third scan flip-flop that configures a scan chain with the first scan flip-flop when a scan mode is set and that outputs retained data in accordance with a clock signal when a normal mode is set; and
a selector that selects the signal outputted from the hardware macro during normal operation, and that selects the retained data of the third scan flip-flop during a test operation and provides the selected signal or data to the combinational circuit.
